(19) United States
(12) Patent Application Publication
(10) Pub. No.: US 2009/0310322 A1
(43) Pub. Date: Dec. 17, 2009

(54) Semiconductor Package

(75) Inventors: Liang Kng Ian Koh, Singapore (SG); Wai Lian Jenny Ong, Singapore (SG); Tham Heang Chew, Singapore (SG); Hai Guan Loh, Singapore (SG)

Correspondence Address: EDELL , SHAPIRO & FINNAN , LLC, 1901 RESEARCH BOULEVARD , SUITE 400, ROCKVILLE, MD, 20850, US

(73) Assignee: INFINEON TECHNOLOGIES AG, Neubiberg (DE)

(21) Appl. No.: 12/496,350

(22) Filed: Jul. 1, 2009

Related U.S. Application Data
(63) Continuation of application No. PCT/IB2007/000057, filed on Jan. 9, 2007.

(51) Int. Cl. H01L 25/11; H01L 21/50

(52) U.S. Cl. 361/783; 438/107; 257/E21.499; 257/E25.027; 257/777

(57) ABSTRACT

A substrate includes a number of protruding contact elements. An electrical circuit with electrical contact elements is provided on the substrate. A layer of substrate adhesive is provided on the substrate, the substrate adhesive being in contact with the substrate, with the electrical circuit and with the protruding contact elements. Wiring elements are connected between the protruding contact elements and the electrical contact elements.

### CROSS REFERENCE TO RELATED APPLICATIONS

This application is a continuation of International Application No. PCT/IB2007/000057, filed on Jan. 9, 2007, entitled “A Semiconductor Package,” the entire contents of which are hereby incorporated by reference.

### FIELD OF THE INVENTION

This application relates to a semiconductor chip package, a method for producing the same, and a superordinate module with a semiconductor package.

### BACKGROUND

A semiconductor chip package typically protects one or more encapsulated semiconductor chips from physical damage. In addition, the semiconductor chip package provides electrical terminals for the transmission of electrical signals to and from external sources to the semiconductor chip.

### SUMMARY

A semiconductor chip package, a method for producing the same, and a superordinate module with a semiconductor package are described herein. According to an embodiment of the present invention, an apparatus comprises a substrate that includes a plurality of substrate barriers. An electrical circuit and a layer of substrate adhesive are provided on the substrate.

The substrate adhesive is in contact with the substrate, with the electrical circuit and with the substrate barriers. A first portion of at least one of the substrate barriers is in contact with the substrate adhesive, while a second portion of the substrate barriers is free of the substrate adhesive. A plurality of electrical chip connectors is connected between the second portions of the substrate barriers and the electrical circuit.

A method of producing the apparatus comprises providing a substrate with a plurality of substrate barriers. An electrical circuit is provided on the substrate. A layer of substrate adhesive is provided between the substrate and the electrical circuit. A plurality of electrical chip connectors is provided between second portions of the substrate barriers and the electrical circuit.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The invention is explained in more detail below with reference to accompanying drawings, where:

FIGS. 1 to 5 illustrate an embodiment of a method for producing a stacked chip package;

FIG. 6 illustrates an embodiment of a flip chip package; and

FIG. 7 illustrates an embodiment of a further stacked chip package mounted on a hand phone module.

### DETAILED DESCRIPTION

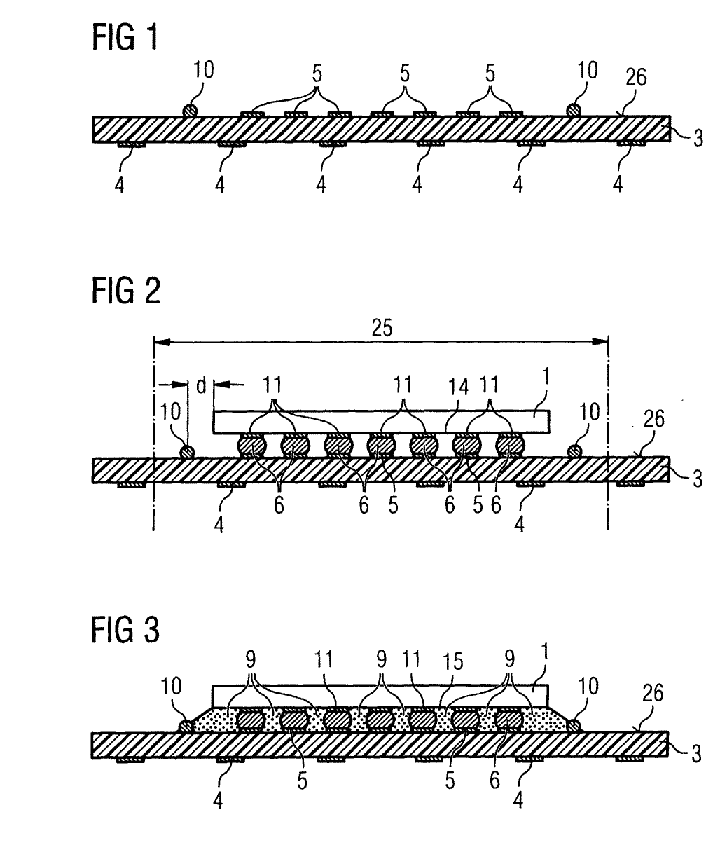

The invention is now described in further detail in relation to exemplary embodiments as depicted in FIGS. 1-7. FIGS. 1 to 5 illustrate, in cross-sectional view, an embodiment of a method for producing a stacked chip package 21.

In FIG. 1, a substrate 3 is provided. The substrate 3 includes an upper surface 26 and a lower surface. The upper surface 26 includes a plurality of flip chip pads 5 that are provided on a central portion of the upper surface 26 and a plurality of gold balls 10. A plurality of solder-pads 4 are provided on the lower surface of the substrate 3. The gold balls 10 act as terminals for electrical connection. The gold ball 10 has the shape of a partly cut ball. The flip chip pads 5 and the gold balls 10 are electrically connected to the solder-pads 4 by a conductive wiring structure that is placed within or on the substrate 3. The wiring structure is not shown in FIG. 1.

FIG. 2 illustrates the substrate 3 of FIG. 1 after a second semiconductor chip 1 has been placed on a chip attachment area 25 of the substrate 3. The chip attachment area 25 is a portion of the upper surface 26 and is slightly bigger than the second semiconductor chip 1. The gold balls 10 are located on a periphery of the chip attachment area 25 such that the gold balls 10 do not lay underneath the second semiconductor chip 1. A reasonable distance d between the gold ball 10 and the second semiconductor chip 1 is in the range of 0.5 um (micrometer) to 1.0 um. The diameter of the gold ball 10 can be in the range of 1 um to 3 um.

The second semiconductor chip 1 comprises a second active surface 14 that is facing downwards (i.e., an underside of the second semiconductor chip 1) and a plurality of second contact pads 11 that are arranged on the second active surface 14. Furthermore, there are electronic circuits disposed within the second semiconductor chip 1, the electronic circuits not being shown in the FIG. 2. The electronic circuits are connected with the second contact pads 11. Solder joints 6 are arranged and extend between the opposing second contact pads 11 and the flip chip pads 5.

FIG. 3 illustrates the substrate of FIG. 2 after a layer of substrate adhesive 9 has been provided as an underfill material between the second semiconductor chip 1 and the substrate 3. The substrate adhesive 9 is in contact with the second semiconductor chip 1, the substrate 3, and the gold balls 10. The substrate adhesive 9 bonds the second semiconductor chip 1 onto the substrate 3 and reduces mechanical stress resulting from the thermal expansion mismatch between the second semiconductor chip 1 and the substrate 3. Moreover, the substrate adhesive 9 is non-conductive and protects the second active surface 14 of the second semiconductor chip 1 from moisture and contaminants.

The substrate adhesive 9 extends over the area covered by the second semiconductor chip 1 such that bottom portions of the gold balls 10 are in physical contact with the substrate adhesive 9 while top portions of the gold balls 10 are not covered by the substrate adhesive 9. The top portions of the gold balls 10 are exposed such that a wire can be attached.

FIG. 4 illustrates the substrate 3 and the second semiconductor chip of FIG. 3 after a layer of chip adhesive 8 has been provided on the top surface of the second semiconductor chip 1. A first semiconductor chip 2 is arranged on the layer of chip adhesive 8. The chip adhesive 8 is in contact with both the first and second semiconductor chips 1 and 2 and bonds the first semiconductor chip 2 to the second semiconductor chip 1.

The first semiconductor chip 2 comprises a first active surface 16 and a plurality of first contact pads 12, which are placed on a periphery of the first active surface 16. The first contact pads 12 are connected to electronic circuits of the first semiconductor chip 2 but are not shown in the FIG. 4.

FIG. 5 illustrates the substrate 3, the second semiconductor chip 1, and the first semiconductor 2 of FIG. 4 with gold wires 7 being attached between the first contact pads 12 and the gold balls 10. The gold wires 7 are attached to the top portions of the gold balls 10, which are not covered by the substrate adhesive 9. The gold wires 7 electrically and physically connect the electronic circuits of the first semiconductor chip 2 and the gold balls 10. Since the gold balls 10 are electrically connected with the solder pads 4, the gold wires 7 also provide electrical connectors between the electronic circuits of the first semiconductor chip 2 and the solder pads 4. An encapsulating compound, which is not shown in the FIG. 5, covers the semiconductor chips 1 and 2, the gold wires 7 and the gold balls 10.

This embodiment illustrates an apparatus that includes a substrate comprising a plurality of contact studs, which can have the form of gold balls. The layer of substrate adhesive may be any known underfill or epoxy material. The attachment area of the substrate is located in the area of the upper surface of the substrate where the semiconductor is arranged. The substrate may be provided as a known printed circuit board PCB. In practice, the electrical wires that connect top portions of the contact studs and the first contact pads are often gold wires.

In the above described embodiment the second semiconductor chip, the chip adhesive, and the first semiconductor chip can be seen to form an integral first semiconductor chip or the chip adhesive, the second semiconductor chip, and the underfill material can be seen as forming an integral substrate adhesive for the first semiconductor chip.

In the above embodiment, the top portion of the contact stud is configured to be a wire attachment area, which being free of substrate adhesive allows the wire attachment area to form reliable attachment with the bonding electrical wire. A wire attachment area that is covered with substrate adhesive would not form reliably attachment with the electrical wire. Contrary to the case in which contact studs are not provided, the contact studs allow the electrical wires to be arranged near the semiconductor chip without risking contact between the electrical wires and the substrate adhesive. The height of the contact stud provides a wire attachment area that is free of substrate adhesive and yet disposed near the semiconductor chip. The close proximity of the electrical wires to the semiconductor chip further permits the semiconductor package to have external dimensions that are close to the external dimensions of the semiconductor chip.

In a broader sense, the embodiment also illustrates an apparatus wherein protruding contact elements are provided in the form of contact studs. Possible forms of protruding contact elements include, but are not limited to, solder deposits or integral components of the substrate. The protruding contact element functions as a substrate barrier that keeps the substrate adhesive away from the bonding area of the electrical chip connectors, which can have the form of wiring elements. The substrate barriers also allow the flow of substrate adhesive in the liquid form before hardening out of the area underneath the electrical circuit. The substrate barriers can also have the shape, inter alia, of a partly hollow structure on the substrate wherein the inner part of the structure is free of substrate adhesive such that, in this case, a bonding can take place directly on the substrate.

The electrical circuit may comprise, inter alia, a plurality of semiconductor chips, which may also be stacked such as in the embodiments in FIGS. 1 to 5. It may further comprise an electrical module (e.g., a printed circuit board (PCB)) or an additional wiring structure in addition or instead of one or more semiconductor chips. The printed circuit board may further include active electronic circuits. Accordingly, the electrical contact-elements may comprise not only contact pads but also other electrically conductive terminals of the electrical circuit.

The wiring elements may comprise electrical wires (e.g., gold wires), and also other conductive materials such as aluminium or copper. They can have the form of a tape or electrical traces on, for example, a flexible PCB which connects the top portions of the protruding contact elements and the first electrical contact elements. The wiring elements are insofar electrical connectors of an electrical chip. In another embodiment not shown in the FIGS. 1 to 5, the contact studs may comprise a conductive material other than gold.

The protruding contact elements are not limited to be placed around the chip attachment area but they can also be located underneath the semiconductor chip. The protruding contact elements and especially the contact studs may be an integral part of the substrate and they can have a shape other than that of a partly cut ball. Moreover, all protruding contact elements may be in contact with the substrate adhesive. This permits the protruding contact elements to be placed near the electrical circuit, thereby allowing an encapsulation of the electrical circuit to be small.

The embodiment may form part of a superordinate electronic module. The superordinate module may comprise several electrical circuits as illustrated in the embodiment. The electrical circuits may comprise semiconductor chips or printed circuit boards PCB. Each electrical circuit is attached to an individual substrate and the individual substrates are connected via a common substrate.

In one embodiment, a method of producing the stack chip package 21 comprises providing a substrate 3, as illustrated in FIG. 1. Following this, the second semiconductor chip 1, as illustrated in FIG. 2, is arranged on the chip attachment area 25 of the substrate 3 (e.g., by an automatic pick-and-place machine). The pick-and-place machine is not shown in FIG. 2. The second active surface 14 of the second semiconductor chip 1 is arranged (e.g., by the automatic pick-and-place machine) facing the substrate 3 such that the solder joints 6 of the second active surface 14 are arranged on the flip chip pads 5 of the substrate 3.

Thereafter, the second semiconductor chip 1 and the substrate 3 are transferred to an oven and are subject to an elevated temperature for a predetermined period. The elevated temperature fuses the solder joints 6 onto the flip chip pads 5 and onto the second contact pads 11, thereby bonding the second semiconductor chip 1 with the substrate 3.

Then, the substrate adhesive 9, as illustrated in FIG. 3, is provided in liquid, non-hardened form between the second semiconductor chip 1 and the substrate 3. The substrate adhesive 9 is dispensed along the edges of the second semiconductor chip 1 using an automated dispenser. The substrate adhesive 9 is drawn underneath the second semiconductor chip 1 by capillary action and makes contact with the bottom surface of the second semiconductor chip 1, the top surface of the substrate 3 and the gold balls 10. The substrate adhesive 9 is then cured and thereby hardened.

After this, the layer of chip adhesive 8, as illustrated in FIG. 4, is applied to the top surface of the second semiconductor chip 1. Then, the first semiconductor chip 2 is arranged on the second semiconductor chip 1 and the chip adhesive 8 is cured.

Following this, the gold wires 7, as illustrated in FIG. 5, are attached between the first contact pads 12 of the first semiconductor chip 2 and the gold balls 10. The gold wires 7 are dispensed by a wire bonder machine which is not shown in FIG. 5.

In a further process, the semiconductor chips 1 and 2, the gold wires 7 and the gold balls 10 are covered with the encapsulating compound to form a finished stacked chip package. The encapsulating compound shields the semiconductor chips 1 and 2, gold wires 7, as well as the gold balls 10 from the surrounding environment. In still a further process, the solder-pads 4 of the substrate 3 can be connected to an external substrate such as a printed circuit board, which is not shown in FIGS. 1 to 5. The embodiment of the method may be implemented with conventional manufacturing tools and material and thus requires minimal investment.

In another embodiment, the substrate adhesive may be applied to the substrate prior to arranging the second semiconductor chip on the substrate rather than after arranging the second semiconductor chip on the substrate.

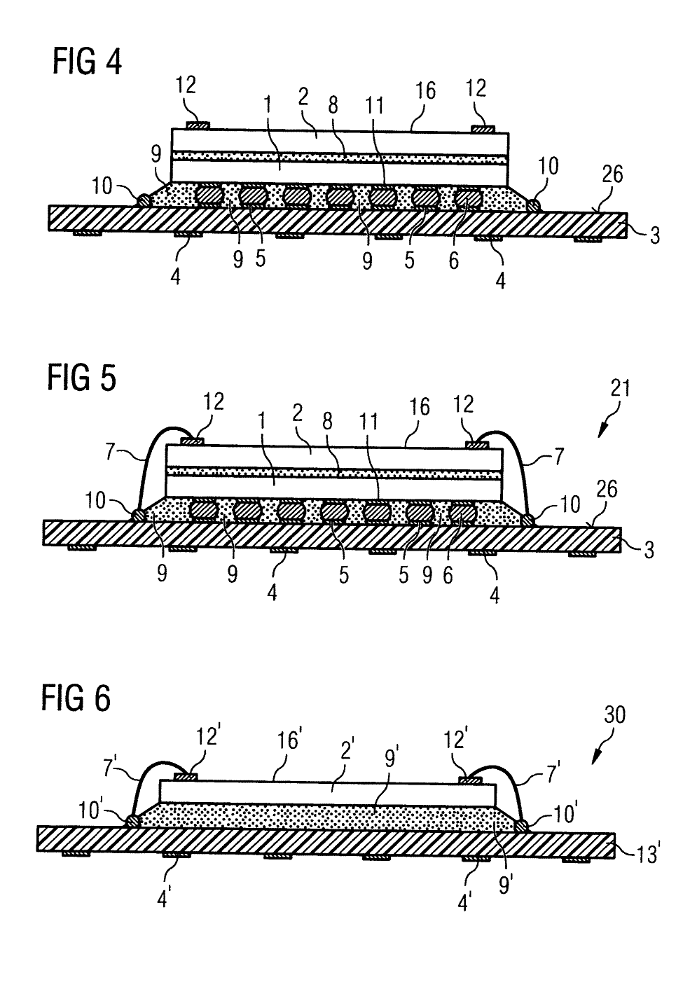

FIG. 6 illustrates, in cross-sectional view, an embodiment of a flip chip package 30. The flip chip package 30 comprises parts that are similar to the parts of the stacked chip package 21 of FIG. 5 or parts that have a similar function as the parts of the stacked chip package 21 of FIG. 5. The description of FIG. 5 is therefore included here by way of reference, where appropriate. Such parts are denoted with the same reference numbers, however, tagged with a prime ′ symbol.

The flip chip package 30 comprises a substrate 13′. A layer of substrate adhesive 9′ is provided on an attachment area of the substrate 13′. A semiconductor chip 2′ is arranged on the layer of substrate adhesive 9′, the layer of substrate adhesive 9′ being in contact with the substrate 13′ and the semiconductor chip 2′.

The substrate 13′ includes a plurality of gold balls 10′ that are arranged on a periphery of the attachment area of the substrate 13′. A plurality of solder pads 4′ are provided on the bottom surface of the substrate 13′. The gold balls 10′ are electrically connected to the solders pads 4′ by a wiring structure within or on the substrate 13′, which is not shown in the FIG. 6. The gold balls 10′ are in contact with the substrate adhesive 9′.

The semiconductor chip 2′ has an active surface 16′ that is facing upward (i.e., away from the substrate 13′ and a plurality of contact pads 12′ that are located on a periphery of the active surface 16′. The semiconductor chip 2′ does not cover the gold balls 10′. A plurality of gold wires 7′ electrically connects the contact pads 12′ to top portions of the gold balls 10′. The top portions of the gold balls 10′ are not in contact with the substrate adhesive 9′ while bottom portions of the gold balls 10′ are in contact with the substrate adhesive 9′. An encapsulating compound, which is not shown in the FIG. 6, covers the semiconductor chip 2′, the gold balls 10′ and the gold wires 7′. For interpreting the embodiment illustrated in FIG. 6 one may also, by way of reference, refer to the explanations and remarks stated above with respect to the embodiment which is illustrated in FIGS. 1 to 5, where appropriate.

The contact studs may have the form of gold balls and the layer of substrate adhesive may also be any known underfill or epoxy material. The substrate may be provided as a known printed circuit board PCB. In practice, the electrical wires being connected between top portions of the contact studs and the first contact pads may be gold wires. With the embodiment illustrated in FIG. 6, when put into practice appropriately, one may be able to achieve essentially similar advantages as with the embodiment illustrated in FIGS. 1 to 5.

The embodiment illustrated in FIG. 6 also allows the wire attachment area to form reliable attachment with the bonding electrical wire and the contact studs allow the electrical wires to be placed near the semiconductor chip without the risk of the electrical wires coming in contact with the substrate adhesive. The semiconductor package can also have external dimensions that are close to the external dimensions of the semiconductor chip.

A method of producing the flip chip package 30 includes providing a substrate 13′ and attaching a plurality of gold balls 10′ on the periphery of an attachment area of the substrate 13′. Thereafter, the semiconductor chip 2′ is arranged on the substrate 13′ with the second active surface 16′ of the semiconductor chip 2′ facing upward (i.e., facing away from the substrate 13′. Subsequently, the layer of liquid substrate adhesive 9′ is applied along the edges of the semiconductor chip 2′. The substrate adhesive 9′ is drawn underneath the semiconductor chip 2′ by capillary action and is in contact with the substrate 13′, with the semiconductor chip 2′ and with the gold balls 10′. Following this, the gold wires 7′ are attached between contact pads 12′ of the semiconductor chip 2′ and the top portions of the gold balls 10′. Then, the encapsulating compound covers the semiconductor chip 2′, the gold balls 10′ and the gold wires 7′.

With the embodiment illustrated in FIG. 6, when put into practice appropriately, one may be able to achieve essentially similar advantages as with the embodiment illustrated in FIGS. 1 to 5. The implementation of the embodiment usually does not require any special manufacturing tools and uses off-the-shelf material. For interpreting the embodiment as illustrated in FIG. 6 one may also, by way of reference, refer to the explanations and remarks stated above with respect to the embodiment which is illustrated in FIGS. 1 to 5, where appropriate.

It is to be understood that the substrate adhesive may also be applied to the substrate prior to arranging the semiconductor chip on the substrate. Rather than, as described in the embodiment above, applying the substrate adhesive to the substrate after arranging the semiconductor chip on the substrate.

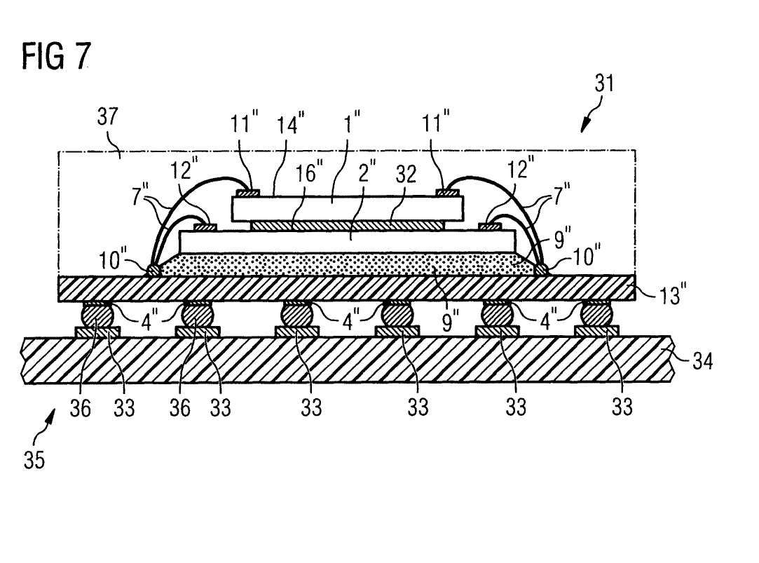

FIG. 7 illustrates, in cross-sectional view, an embodiment of a further stacked chip package 31 mounted on a superordinate electronic module 35 (e.g., a hand phone module). The further stacked chip package 31 comprises parts that are similar to the parts of the chip packages of FIGS. 5 and 6 or parts that have a similar function as the parts of the chip packages of FIG. 5 or FIG. 6. The descriptions of FIGS. 5 and 6 are therefore included here by way of reference, where appropriate. Such parts are denoted with the same reference numbers but tagged with a double prime ″ symbol.

The stacked chip package 31 comprises a substrate 13″. A layer of substrate adhesive 9″ is disposed on an attachment-area of the substrate 13″. A first semiconductor chip 2″ is provided on the substrate adhesive 9″. Spacer 32 is arranged on the first semiconductor chip 2″. A second semiconductor chip 1″ is disposed on top of the spacer 32.

The substrate 13″ includes a plurality of gold balls 10″ that are placed on an outer area of the attachment-area of the substrate 13″, which is not located underneath the first semiconductor chip 2″. Bottom portions of the gold balls 10″ are in contact with the substrate adhesive 9″ while top portions of the gold balls 10″ are free of the substrate adhesive 9″. The gold balls 10″ may be located in the vicinity of the first semiconductor chip 2″. The substrate adhesive 9″ is in contact with the top surface of the substrate 13″ and the bottom surface of the first semiconductor chip 2″.

The first semiconductor chip 2″ comprises a plurality of first contact pads 12″, which are provided on an outer area of the surface of the first semiconductor chip 2″. A plurality of gold wires 7″ electrically connects the first contact pads 12″ to the top portions of the gold balls 10″. The spacer 32 is disposed between the second semiconductor chip 1″ and to the first semiconductor chip 2″ and thereby provides not only a mechanical separation between the second semiconductor chip 1″ and the first semiconductor chip 2″ but also electrically isolates the electronic circuits of the second semiconductor chip 1″ and those of the first semiconductor chip 2″.

The second semiconductor chip 1″ comprises a plurality of second contact pads 11″, which are provided on an outer area of the surface of the second semiconductor chip 1″. A plurality of gold wires 7″ electrically connects the second contact pads 11″ to the top portions of the gold balls 10″. An encapsulation 37 covers the second semiconductor chip 1″, the first semiconductor chip 2″, the gold balls 10″ and the gold wires 7″. An outline of the encapsulation 37 is shown in the FIG. 7. The Figures of the earlier embodiments do not show the encapsulation 37; however, these embodiments may further comprise encapsulation 37.

The stacked chip package 31 is provided on a top surface of a superordinate electronic module 35 (e.g., a hand phone module). The superordinate module includes a printed circuit board PCB 34 and a plurality of module contacts 33 that are provided on top surface of the PCB 34.

A solder ball 36 is provided between the opposing module contact 33 and the solder pad 4″ of the substrate 13″. The solder ball 36 bonds with the module contact 33 and the solder pad 4″, and thereby bonding the superordinate module 35 (e.g., a hand phone module) to the stacked chip package 31.

The module contacts 33 are connected to electronic circuits that are mounted on the PCB 34. These electronics circuits are not shown in the FIG. 7. The solder ball 36 acts as an electrical terminal transmitting electrical signals. The electrical signals are transmitted between the electronic circuits of the superordinate electronic module 35 (e.g., a hand phone module) and the electronic circuits of the stacked chip package 21.

The electronics circuits of the superordinate module 35 (e.g., hand phone module) may, for example, convert analogy voice signals to electrical digital signals while the first and the second semiconductor chips 2″ and 1″ modulate the electrical digital signals into a form ready for external transmission.

It is to be understood that the embodiment illustrated in FIG. 7, may also, by way of reference, refer to the explanations and remarks stated with respect to the embodiment that is illustrated in FIGS. 1 to 5 or FIG. 6, where appropriate.

The superordinate electronic module may be the form of a hand phone module and it may include more than one semiconductor chip package. A printed circuit board PCB may also replace the semiconductor chip package. The superordinate electronic module usually integrates the functions of the semiconductor chip or printed circuit board PCB to provide a higher-level function.

The substrate may also have the form of a printed circuit board PCB. The contact studs may be formed by gold balls, either in the form of a full sphere or in the form of a partly cut sphere. The layer of substrate adhesive may comprise a bonding material such as an underfill or an epoxy material. The electrical wires attaching the top portions of the contact studs to the first contact pads may be gold wires but may also be aluminium or copper wires.

The embodiment as illustrated in FIG. 7 has similar advantages as that of the embodiments illustrated in FIGS. 1 to 6. The embodiment of FIG. 7 allows reliable wire attachment to be formed on the substrate. The electrical wire may be attached to an area near the semiconductor chip. This enables the size of semiconductor chip package to be compact in that the external dimensions of the semiconductor chip package may be close to the external dimensions of the semiconductor chip.

The spacer that is placed between the second semiconductor chip and the first semiconductor chip may include a bonding material for bonding to the second semiconductor chip and to the first semiconductor chip. This bonding fixes the second semiconductor chip to the first semiconductor chip and prevents the second semiconductor chip from shifting. A shift in the position of the second semiconductor chip may hinder the later placement of an electrical element such as electrical wires onto to the second semiconductor chip. In a generic sense, the electrical circuit can comprise, inter alia, a plurality of semiconductor chips, which may also be stacked such as in the embodiments in FIG. 7.

A method of producing the stacked chip package 31, as illustrated in FIG. 7, comprises providing the substrate 13″. Following this, the plurality of gold balls 10″ is attached to the periphery of attachment area of the substrate 13″. Afterwards, the first semiconductor chip 2″ is arranged on the substrate 13″. Subsequently, a layer of liquid substrate adhesive 9″ is applied along the edges of the first semiconductor chip 2″. The substrate adhesive 9″ is drawn underneath the first semiconductor chip 2″ by capillary action and is in contact with the bottom portions of the gold balls 10″, with the substrate 13″ and with the first semiconductor chip 2″.

Then, the spacer 32 is arranged on top of the first semiconductor chip 2″. Next, the second semiconductor chip 1 is arranged on the spacer 32. Following this, the gold wires 7″ are attached between the first contact pads 12″ and the gold balls 10″ and between second contact pads 11″ and the gold balls 10″. Then, the encapsulating compound is applied and covers the second semiconductor chip 1″, the first semiconductor chip 2″, the gold balls 10″ and the gold wires 7″ thereby forming the encapsulation 37.

After this, the stacked chip package 31 is arranged on the PCB 34. Then, the stacked chip package 31 and the PCB 34 are subjected to an elevated temperature for a predetermined period. This fuses the solder ball 36 onto the solder pad 4″ and onto the module contact 33, thereby attaching the stacked chip package 31 to the superordinate electronic module 35 (e.g., a hand phone module).

With the embodiment illustrated in FIG. 7, when put into practice appropriately, one may be able to achieve essentially similar advantages as with the embodiment illustrated in FIGS. 1 to 5 or FIG. 6. The embodiment of the method illustrated in FIG. 7 shows the integration of the semiconductor chip with an external printed circuit board PCB. The embodiment of the method does not require investment in special manufacturing tools or materials.

For interpreting the embodiment illustrated in FIG. 7 one may also, by way of reference, refer to the explanations and remarks stated above with respect to the embodiment which is illustrated in FIGS. 1 to 5 or FIG. 6, where appropriate. In practice, the semiconductor chip package and the printed circuit board PCB may be produced in the same or different location by the same or different manufacturing organization. The printed circuit board PCB may also be connected to more than one semiconductor chip packages.

The embodiments can also be described with the following lists of elements being organized into items. According to one embodiment, an apparatus comprises: a substrate comprising a plurality of contact studs, a first semiconductor chip being disposed on an attachment area of the substrate, and a layer of substrate adhesive disposed on the attachment area of the substrate, and a plurality of electrical wires. The first semiconductor chip comprises a plurality of contact pads. The substrate adhesive is in contact with the substrate, the first semiconductor chip and the contact studs such that a bottom portion of at least one of the contact studs is in contact with the substrate adhesive, while a top portion of the contact stud is free of the substrate adhesive. Furthermore, the plurality of electrical wires is connected between the top portions of the contact studs and the contact pads.

According to embodiments of the invention, the substrate adhesive may comprise a curable underfill material. The contact stud may have the shape of a partly cut sphere. Furthermore, the apparatus may further comprise a second semiconductor chip being disposed on top of the first semiconductor chip. The apparatus may further comprise a printed circuit board. According to a further embodiment, a superordinate electronic module may comprise the apparatus described above.

According to a second embodiment, an apparatus comprises: a substrate including a plurality of contact studs, a first semiconductor chip being provided on an attachment area of the substrate, a second semiconductor chip being provided between the first semiconductor chip and the substrate, a layer of substrate adhesive being provided on the attachment area of the substrate, and a plurality of electrical wires. Furthermore, the first semiconductor chip comprises a plurality of first contact pads. The substrate adhesive is in contact with the substrate, the second semiconductor chip and the contact studs such that a bottom portion of at least one of the contact studs is in contact with the substrate adhesive, while a top portion of the contact stud is free of the substrate adhesive. The plurality of electrical wires is connected between the top portions of the contact studs and the first contact pads.

Furthermore, the substrate adhesive may comprise a curable underfill material. The contact stud may have a shape of a partly cut sphere. The substrate may further comprise a printed circuit board. The apparatus may further comprise a spacer disposed between the first and second semiconductor chips. According to a further embodiment, a superordinate electronic module may comprise the apparatus described above in connection with the second embodiment.

According to a third embodiment, an apparatus comprises: a substrate comprising a plurality of protruding contact elements, an electrical circuit being provided on the substrate, a layer of substrate adhesive being provided on the substrate. The substrate adhesive is in contact with the substrate, the electrical circuit and the protruding contact elements such that a bottom portion of at least one of the protruding contact elements is in contact with the substrate adhesive, while a top portion of the protruding contact element is free of the substrate adhesive. The apparatus further comprises a plurality of wiring elements being connected between the top portions of the protruding contact elements and the electrical circuit. Furthermore, the electrical circuit may comprise at least one semiconductor chip; for example, the electrical circuit may comprise at least two semiconductor chips arranged in a stack. Furthermore, the electrical circuit may comprise at least one electrical module; for example, the electrical circuit may comprise at least two electrical modules arranged in a stack. According to a further embodiment, a superordinate electronic module may comprise the apparatus described above in connection with the third embodiment.

According to a fourth embodiment, an apparatus comprises: a substrate including a plurality of substrate barriers, an electrical circuit being provided on the substrate, a layer of substrate adhesive being provided on the substrate, and a plurality of electrical chip connectors. The substrate adhesive is in contact with the substrate, the electrical circuit and the substrate barriers such that a bottom portion of at least one of the substrate barriers is in contact with the substrate adhesive, while a top portion of the substrate barriers is free of the substrate adhesive. Furthermore, the plurality of electrical chip connectors is connected between the top portions of the substrate barriers and the electrical circuit.

Furthermore, the substrate adhesive may comprise a curable underfill material. The substrate barriers may comprise a shape of a partly cut sphere. The substrate may comprise a printed circuit board. According to a further embodiment, a superordinate electronic module may comprise the apparatus described above in connection with the fourth embodiment.

A method for producing a chip package according to an embodiment comprises: providing a substrate, arranging a plurality of contact studs on the substrate, arranging a first semiconductor chip with a plurality of first contact pads on the substrate. The method further comprises applying a layer of substrate adhesive between the substrate and the first semiconductor chip such that the substrate adhesive is in contact with the substrate, the first semiconductor chip and a bottom portion of the contact stud and such that a top portion of the contact stud is free of the substrate adhesive. The method further comprises connecting a plurality of electrical wires between the top portions of the contact studs and the first contact pads.

A method for producing a chip package according to another embodiment comprises: providing a substrate, arranging a plurality of contact studs on the substrate, and arranging a second semiconductor chip on the substrate. The method further comprises providing a layer of substrate adhesive between the substrate and the second semiconductor chip such that the substrate adhesive is in contact with the substrate, the second semiconductor chip, and a bottom portion of the contact stud and such that a top portion of the contact stud is free of the substrate adhesive. The method further comprises arranging a first semiconductor chip on the second semiconductor chip, the first semiconductor chip comprising a plurality of first contact pads. The method further comprises connecting a plurality of electrical wires between the top portions of the contact studs and the first contact pads.

A method according to yet another embodiment comprises: providing a substrate, arranging a plurality of protruding contact elements on the substrate, and arranging an electrical circuit on the substrate. The method further comprises applying a layer of substrate adhesive between the substrate and the electrical circuit such that the substrate adhesive is in contact with the substrate, the electrical circuit and a bottom portion of the protruding contact elements, and such that a top portion of the protruding contact elements is free of the substrate adhesive. The method further comprises connecting a plurality of wiring elements between the top portions of the protruding contact elements and the electrical circuit.

Although the above descriptions contain many details with reference to specific embodiments thereof, these should not be construed as limiting the scope of the embodiments but merely providing illustration to one of ordinary skill in the art of the foreseeable embodiments and that various changes and modifications can be made therein without departing from the spirit and scope thereof. Especially the above stated advantages of the embodiments should not be construed as limiting the scope of the embodiments but merely to explain possible achievements if the described embodiments are put into practice. Thus, the scope of the embodiments should be determined by the claims and their equivalents, rather than by the examples given.

What is claimed is:

1. An apparatus, comprising:
a substrate including a plurality of substrate barriers respectively including first portions and second portions;
an electrical circuit disposed on the substrate;
a layer of substrate adhesive disposed on the substrate and in contact with the substrate, the electrical circuit, and the first portions of the substrate barriers, such that the second portions of the substrate barriers are free of the substrate adhesive; and
a plurality of electrical chip connectors connected between the second portions of the substrate barriers and the electrical circuit.

2. The apparatus according to claim 1, wherein the substrate barriers comprise protruding contact elements, the first portions comprising bottom portions of the protruding contact elements and the second portions comprising top portions of the protruding contact elements.

3. The apparatus according to claim 2, wherein the protruding contact elements comprise contact studs.

4. The apparatus according to claim 3, wherein the contact studs have the shape of a partly cut sphere.

5. The apparatus according to claim 1, wherein the electrical circuit comprises at least one electrical module.

6. The apparatus according to claim 5, wherein the electrical circuit comprises at least two electrical modules arranged in a stack.

7. The apparatus according to claim 5, wherein at least one electrical module comprises at least one semiconductor chip.

8. The apparatus according to claim 7, wherein the electrical module comprises a first semiconductor chip, the first semiconductor chip being disposed on an attachment area of the substrate and the substrate adhesive being in contact with the first semiconductor chip.

9. The apparatus according to claim 8, wherein the electrical module comprises a second semiconductor chip, the second semiconductor chip being disposed on top of the first semiconductor chip.

10. The apparatus according to claim 7, wherein the at least one electrical module comprises a second semiconductor chip disposed between the first semiconductor chip and the substrate, the substrate adhesive being in contact with the second semiconductor chip.

11. The apparatus according to claim 10, wherein the at least one electrical module comprises a spacer disposed between the first semiconductor chip and the second semiconductor chip.

12. The apparatus according to claim 1, wherein the electrical chip connectors comprise a wiring element.

13. The apparatus according to claim 12, wherein the wiring element comprises an electrical wire.

14. The apparatus according to claim 1, wherein the substrate adhesive comprises a curable underfill material.

15. The apparatus according to claim 1, wherein the substrate comprises a printed circuit board.

16. A superordinate electronic module, comprising the apparatus of claim 1.

17. A method, comprising:
providing a substrate;
arranging on the substrate a plurality of substrate barriers respectively including first portions and second portions;
arranging an electrical circuit on the substrate;
applying a layer of substrate adhesive between the substrate and the electrical circuit such that the substrate adhesive is in contact with the substrate, the electrical circuit, and first portions of the substrate barriers and such that the second portions of the substrate barriers are free of the substrate adhesive; and
connecting a plurality of electrical chip connectors between the second portions of the substrate barriers and the electrical circuit.

18. The method according to claim 17, wherein arranging an electrical circuit on the substrate comprises arranging a first semiconductor chip on the substrate.

19. The method according to claim 18, wherein arranging an electrical circuit on the substrate comprises arranging a second semiconductor chip on the first semiconductor chip.

20. The method according to claim 18, wherein the substrate barriers comprise contact studs, the first portions comprising bottom portions of the contact studs and the second portions comprising top portions of the contact studs, and wherein applying the layer of substrate adhesive comprises applying a layer of substrate adhesive between the substrate and a first semiconductor chip such that the substrate adhesive is in contact with the substrate, the first semiconductor chip, and the bottom portions of the contact studs and such that the top portions of the contact studs are free of the substrate adhesive.

21. The method according to claim 20, wherein connecting a plurality of electrical chip connectors comprises connecting a plurality of electrical wires between the top portions of the contact studs and the first semiconductor chip.
